(19) United States
(12) Patent Application Publication
(10) Pub. No.: US 2007/0165753 A1
(43) Pub. Date: Jul. 19, 2007

(54) IMPULSE NOISE REMOVER AND RELATED METHOD

(76) Inventor: Shun-An Yang, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 11/306,915

(22) Filed: Jan. 16, 2006

(51) Int. Cl. H03D 1/04

(52) U.S. Cl. 375/346

(57) ABSTRACT

An impulse noise remover includes a delay chain, a plurality of detection modules coupled to the delay chain, a logic unit coupled to the detection modules, and a multiplexer coupled to the delay chain and the logic unit. The delay chain delays the input signal to generate a plurality of delayed signals. The delayed signals and the input signal constitute a reference signal set. Each of the detection modules generates an indication signal according to a threshold value and a signal subset of the reference signal set. The logic unit generates a control signal according to a plurality of indication signals generated by the detection modules. The multiplexer selectively outputs a padding value or one of the delayed signals as the output signal according to the control signal.

### BACKGROUND

The present invention relates to impulse noise, and more particularly, to an apparatus that adaptively detects and removes impulse noise in an input signal.

All kinds of receivers are susceptible to various forms of noise that can disrupt reception. Impulse noise, which comprises one or more pulses with relatively high amplitude and short duration, is a commonly encountered noise. Generally speaking, sources of impulse noise include microwave ovens, washing machines, light switches, car engines, and other electrical machines. Severe impulse noise can degrade signal reception quality and cause burst errors to occur. To ensure correct signal reception, system designers often install an apparatus in the receiving path of a receiver to detect impulse noise and remove it.

However, since impulse noise can have various different properties, detection of impulse noise is a complex task. In the related art, for example, an impulse noise remover detects impulse noise by comparing the amplitude of a received signal with a predetermined threshold. If the amplitude of the received signal is larger than the predetermined threshold, some samples of the received signal before and after the detected impulse noise are set to 0. If the threshold is small, some samples with higher amplitude in the received signal might be erroneously treated as impulse noise. To avoid these kinds of false alarms occurring, the impulse noise remover of the related art is always preset with a high threshold. The setting of this high threshold will only allow impulse noise having large amplitude to be detected. Impulse noise with amplitude smaller than the threshold can pass through the impulse noise detector easily without being detected. Signal reception quality is therefore deteriorated by the undetected impulse noise.

### SUMMARY

The embodiments disclose an impulse noise remover. The impulse noise remover comprises a delay chain, a plurality of detection modules coupled to the delay chain, a logic unit coupled to the detection modules, and a multiplexer coupled to the delay chain and the logic unit. The delay chain delays the input signal to generate a plurality of delayed signals. The delayed signals and the input signal constitute a reference signal set. Each of the detection modules generates an indication signal according to a threshold value and a signal subset of the reference signal set. The logic unit generates a control signal according to a plurality of indication signals generated by the detection modules. The multiplexer selectively outputs a padding value or one of the delayed signals as the output signal according to the control signal.

The embodiments also disclose another impulse noise remover. The impulse noise remover comprises a delay chain, a calculator coupled to the delay chain, a plurality of detection modules coupled to the calculator, a logic unit coupled to the detection modules, and a multiplexer coupled to the delay chain and the logic unit. The delay chain delays the input signal to generate a plurality of delayed signals. The delayed signals and the input signal constitute a reference signal set. The calculator calculates a reference value according to a signal subset of the reference signal set. Each of the detection modules generates an indication signal according to a threshold value and the reference value. The logic unit generates a control signal according to a plurality of indication signals generated by the detection modules. The multiplexer selectively outputs a padding value or one of the delayed signals as the output signal according to the control signal.

### BRIEF DESCRIPTION OF THE DRAWINGS

FIG. 1 shows a block diagram of an impulse noise remover according to a first embodiment.

FIG. 2 shows a block diagram depicting the detection modules of FIG. 1 in detail.

FIG. 3 shows a block diagram of an impulse noise remover according to a second embodiment.

FIG. 4 shows a block diagram depicting the detection modules of FIG. 3 in detail.

### DETAILED DESCRIPTION

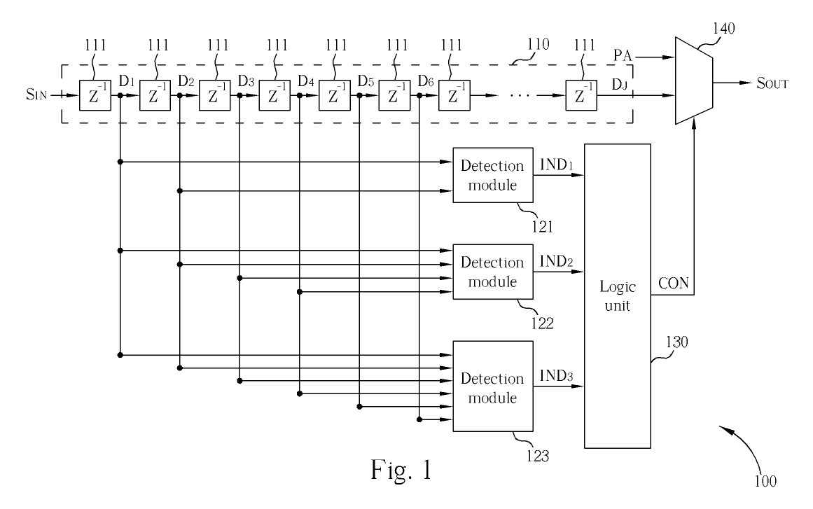

Please refer to FIG. 1, where an impulse noise remover 100 according to a first embodiment is disclosed. A signal S_{IN} comprising a series of digital samples constitutes an input signal of the impulse noise remover 100; and a signal S_{OUT} comprising a series of digital samples constitutes an output signal of the impulse noise remover 100. The impulse noise remover 100 of this embodiment comprises a delay chain 110, a plurality of detection modules 121˜123, a logic unit 130, and a multiplexer 140.

The delay chain 110 comprises a plurality of delay units 111 and delays the input signal S_{IN} to generate a plurality of delayed signals D₁˜D_{J}, wherein _{J} is a positive integer larger than 1. Each of the delayed signals D₁˜D_{J} has a different delay with respect to the input signal S_{IN}. The input signal S_{IN} and the delayed signals D₁˜D_{J} constitutes a reference signal set. Each of the detection modules 121˜123 generates an indication signal according to a threshold value and a signal subset of the reference signal set. The logic unit 130 generates a control signal CON according to a plurality of indication signals IND₁˜IND₃ generated by the detection modules 121˜123. The multiplexer 140 selectively outputs a padding value PA or a delayed signal D_{J} as the output signal S_{OUT} according to the control signal CON. Herein ‘zero’ serves as an example of the padding value PA.

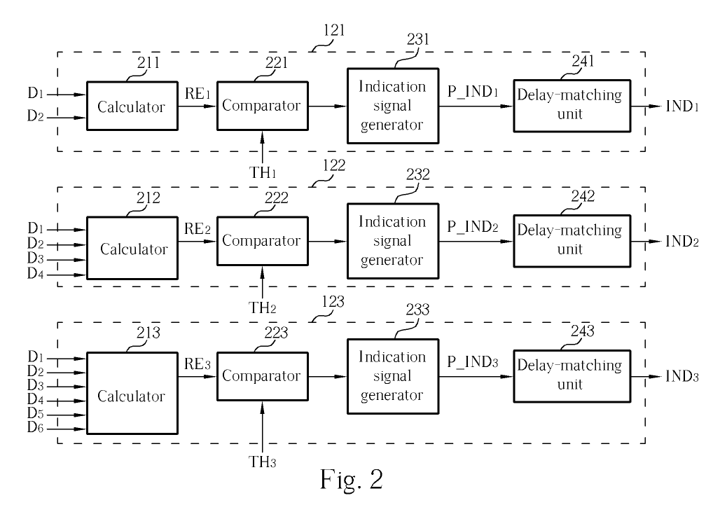

FIG. 2 shows an exemplary block diagram depicting the detection modules 121˜123 of FIG. 1 in detail. Each of the detection modules 121˜123 comprises a calculator, a comparator, an indication signal generator, and a delay-matching unit. Taking the detection module 121 as an example, the calculator 211 calculates a first reference value RE₁ according to a first signal subset {D₁, D₂} of the reference signal set. The absolute sum of the signals included in the first signal subset {D₁, D₂} serves as an example of the first reference value RE₁, that is, RE₁=abs(D₁)+abs(D₂). The comparator 221 compares the first reference value RE₁ with a first threshold value TH₁. The indication signal generator 231 generates a first primitive indication signal P_{—IND}₁ according to the comparing result generated by the comparator 221. If the comparison result generated by the comparator 221 shows that the first reference value RE₁ exceeds the first threshold value TH₁, the indication signal generator 231 asserts a first amount of samples in the first primitive indication signal P_IND₁ so as to indicate a first amount of invalid samples in the input signal S_{IN}. The first amount of invalid samples in the input signal S_{IN} are those samples that have possibly been corrupted by impulse noise. The delay-matching unit 241 delays the first primitive indication signal P_IND₁ to generate a first indication signal IND₁. The goal of setting the delay-matching unit 241 in the first detection modules 121 is to ensure that the first indication signal IND₁ arrives at the logic unit 130 at a correct timing. Please note that the delay-matching unit 241 can also be set in other positions of the detection module 121.

As for the detection module 122, the components included therein allows it to calculate a second reference value RE₂ according to a second signal subset {D₁, D₂, D₃, D₄} of the reference signal set, compare the second reference value RE₂ with a second threshold value TH₂, generate a second primitive indication signal P_IND₂ according to the comparison result, and delay the second primitive indication signal P_IND₂ to generate a second indication signal IND₂. The absolute sum of the signals included in the second signal subset {D₁, D₂, D₃, D₄} serves as an example of the second reference value RE₂, that is, RE₂=abs (D₁)+abs(D₂)+abs(D₃)+abs(D₄). Similarly, the components included in the detection module 123 allows it to calculate a third reference value RE₃ according to a third signal subset {D₁, D₂, D₃, D₄, D₅, D₆} of the reference signal set, compare the third reference val RE₃ with a third threshold value TH₃, generate a third primitive indication signal P_IND₃ according to the comparison result, and delay the third primitive indication signal P_IND₃ to generate a third indication signal IND₃. The absolute sum of the signals included in the third signal subset {D₁, D₂, D₃, D₄, D₅, D₆} serves as an example of the third reference value RE₃, that is, RE₃=abs(D₁)+abs(D₂)+abs(D₃)+abs(D₄)+abs(D₅)+abs(D₆). If the second reference value RE₂ exceeds the second threshold value TH₂, a second amount of samples in the second indication signal IND₂ will be asserted so as to indicate a second amount of invalid samples in the input signal S_{IN}. Similarly, if the third reference value RE₃ exceeds the third threshold value TH₃, a third amount of samples in the third indication signal IND₃ Will be asserted so as to indicate a third amount of invalid samples in the input signal S_{IN}.

Referring back to FIG. 1, an OR gate can implement the logic unit 130. When at least one of the indication signals IND₁˜IND₃ is asserted, the control signal CON will also be asserted, and the multiplexer 140 will output the padding value PA as the output signal S_{OUT}. When none of the indication signals IND₁˜IND₃ is asserted, neither will the control signal CON be asserted. The multiplexer 140 will output the delayed signal D_{J} as the output signal S_{OUT}. Therefore, samples in the input signal S_{IN} that are possibly influenced by impulse noise will be replaced by the padding value PA in the output signal S_{OUT}; samples in the input signal S_{IN} that are not influenced by impulse noise will pass through the impulse noise remover 100 to become the output signal S_{OUT}.

Since the detection modules 121˜123 utilizes different signal subsets of the reference signal set and different threshold values to detect impulse noise, each of the detection modules 121˜123 can detect impulse noise with different characteristics. When impulse noise with different characteristics is detected by the detection modules 121˜123, different amounts of samples in the input signal S_{IN} will be treated as invalid samples and will be replaced by the padding value PA. Therefore, different kinds of impulse noise will be treated differently. In other words, with the impulse noise remover 100 of this embodiment, impulse noise in the input signal S_{IN} will be detected and removed adaptively.

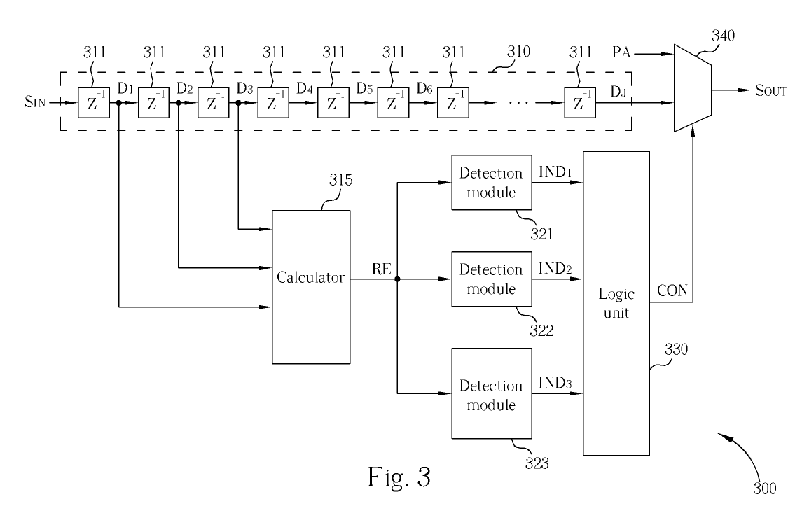

Please refer to FIG. 3, where an impulse noise remover 300 according to a second embodiment is disclosed. A signal S_{IN} comprising a series of digital samples constitutes an input signal of the impulse noise remover 300; and a signal S_{OUT} comprising a series of digital samples constitutes an output signal of the impulse noise remover 300. The impulse noise remover 300 of this embodiment comprises a delay chain 310, a calculator 315, a plurality of detection modules 321˜323, a logic unit 330, and a multiplexer 340.

The delay chain 310 comprises a plurality of delay units 311 and delays the input signal S_{IN} to generate a plurality of delayed signals D₁-D_{J}, wherein _{J} is a positive integer larger than 1. Each of the delayed signals D₁˜D_{J} has a different delay with respect to the input signal S_{IN}. The input signal S_{IN} and the delayed signals D₁˜D_{J} constitutes a reference signal set. The calculator 315 calculates a reference value RE according to a signal subset {D₁, D₂, D₃} of the reference signal set. Herein the absolute sum of the signals included in the signal subset {D₁, D₂, D₃} serves as an example of the reference value RE, that is, RE=abs(D₁)+abs(D₂)+abs(D₃). Each of the detection modules 321˜323 generates an indication signal according to a threshold value and the reference value RE. The logic unit 330 generates a control signal CON according to a plurality of indication signals IND₁˜IND₃ generated by the detection modules 321˜323. The multiplexer 340 selectively outputs a padding value PA or a delayed signal D_{J} as the output signal S_{OUT} according to the control signal CON. Herein ‘zero’ serves as an example of the padding value PA.

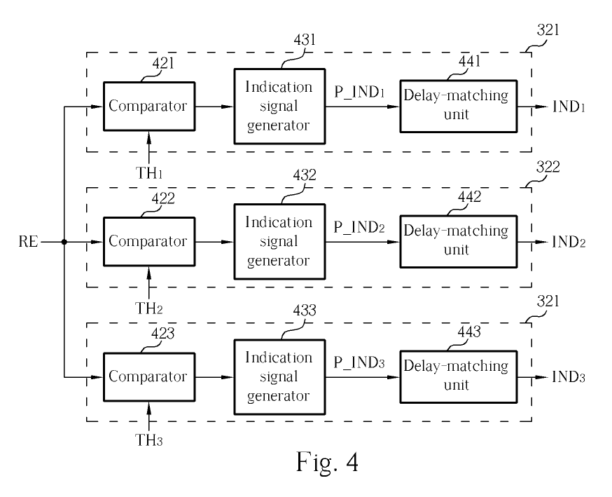

FIG. 4 shows an exemplary block diagram depicting the detection modules 321˜323 of FIG. 3 in detail. Each of the detection modules 321˜323 comprises a comparator, an indication signal generator, and a delay-matching unit. Taking the detection module 321 as an example, the comparator 421 compares the reference value RE with a first threshold value TH₁. The indication signal generator 431 generates a first primitive indication signal P_IND₁ according to the comparing result generated by the comparator 421. If the comparison result generated by the comparator 421 shows that the reference value RE exceeds the first threshold value TH₁, the indication signal generator 431 asserts a first amount of samples in the first primitive indication signal P_IND₁ so as to indicate a first amount of invalid samples in the input signal S_{IN}. The first amount of invalid samples in the input signal S_{IN} are those that have possibly been corrupted by impulse noise. The delay-matching unit 441 delays the first primitive indication signal P_IND₁ to generate a first indication signal IND₁. The goal of setting the delay-matching unit 441 in the first detection modules 321 is to ensure that the first indication signal IND₁ arrives at the logic unit 330 at a correct timing. Please note that the delay-matching unit 441 can also be set in other positions of the detection module 321.

As for the detection module 322, the components included therein allows it to compare the reference value RE with a second threshold value TH₂, generate a second primitive indication signal P_IND₂ according to the comparing result, and delay the second primitive indication signal P_IND₂ to generate a second indication signal IND₂. Similarly, the components included in the detection module 323 allows it to compare the reference value RE with a third threshold value TH₃, generate a third primitive indication signal P_IND₃ according to the comparison result, and delay the third primitive indication signal P_IND₃ to generate a third indication signal IND₃. If the reference value RE exceeds the second threshold value TH₂, a second amount of samples in the second indication signal IND₂ Will be asserted so as to indicate a second amount of invalid samples in the input signal S_{IN}. If the reference value RE exceeds the third threshold value TH₃, a third amount of samples in the third indication signal IND₃ will be asserted so as to indicate a third amount of invalid samples in the input signal S_{IN}.

Please refer back to FIG. 3. An OR gate can implement the logic unit 330. When at least one of the indication signals IND₁˜IND₃ is asserted, the control signal CON will also be asserted, and the multiplexer 340 will output the padding value PA as the output signal S_{OUT}. When none of the indication signals IND₁˜IND₃ is asserted, neither will the control signal CON be asserted. The multiplexer 340 will output the delayed signal D_{J} as the output signal S_{OUT}. Therefore, samples in the input signal S_{IN} that are possibly influenced by impulse noise will be replaced by the padding value PA in the output signal S_{OUT}; samples in the input signal S_{IN} that are not influenced by impulse noise will pass through the impulse noise remover 300 to become the output signal S_{OUT}.

Since the detection modules 321˜323 utilizes different threshold values to detect impulse noise, each of the detection modules 321˜323 can detect impulse noise with different strength. When impulse noise with different strength is detected by the detection modules 121˜123, different amounts of samples in the input signal S_{IN} will be treated as invalid samples and will be replaced by the padding value PA. When the reference value RE exceeds larger threshold value, more samples in the input signal S_{IN} should be replaced by the padding value PA in the output signal S_{OUT}. Therefore, in one example, the first threshold TH₁<the second threshold TH₂<the third threshold TH₃, while the first amount <the second amount <the third amount.

What is claimed is:

1. An impulse noise remover for removing impulse noise from an input signal to generate an output signal, the impulse noise remover comprising:
a delay chain for delaying the input signal to generate a plurality of delayed signals, the input signal and the delayed signals constituting a reference signal set;
a plurality of detection modules coupled to the delay chain, each of the detection modules generating an indication signal according to a threshold value and a signal subset of the reference signal set;
a logic unit coupled to the detection modules for generating a control signal according to a plurality of indication signals generated by the detection modules; and
a multiplexer coupled to the delay chain and the logic unit, for selectively outputting a padding value or one of the delayed signals as the output signal according to the control signal.

2. The impulse noise remover of claim 1, wherein a plurality of signal subsets utilized by the detection modules are different from each other.

3. The impulse noise remover of claim 1, wherein a plurality of threshold values utilized by the detection modules are different from each other.

4. The impulse noise remover of claim 1, wherein each of the detection modules comprises:
a calculator coupled to the delay chain, for calculating a reference value according to a signal subset of the reference signal set;
a comparator coupled to the calculator, for comparing the reference value with a threshold value;
an indication signal generator coupled to the comparator, for generating a primitive indication signal according to a comparison result generated by the comparator; and
a delay-matching unit coupled to the indication signal generator and the logic unit, for delaying the primitive indication signal to generate an indication signal.

5. The impulse noise remover of claim 4, wherein the calculator calculates an absolute sum of signals included in the signal subset to be the reference value.

6. The impulse noise remover of claim 4, wherein the indication signal generator generates the primitive indication signal to indicate an amount of invalid samples in the input signal if the comparing result indicates that the reference value exceeds the threshold value.

7. An impulse noise remover for removing impulse noise from an input signal to generate an output signal, the impulse noise remover comprising:
a delay chain for delaying the input signal to generate a plurality of delayed signals, the input signal and the delayed signals constituting a reference signal set;
a calculator coupled to the delay chain, for calculating a reference value according to a signal subset of the reference signal set;
a plurality of detection modules coupled to the calculator, each of the detection modules generating an indication signal according to the reference value and a threshold value;
a logic unit coupled to the detection modules for generating a control signal according to a plurality of indication signals generated by the detection modules; and
a multiplexer coupled to the delay chain and the logic unit, for selectively outputting a padding value or one of the delayed signals as the output signal according to the control signal.

8. The impulse noise remover of claim 7, wherein a plurality of threshold values utilized by the detection modules are different from each other.

9. The impulse noise remover of claim 7, wherein each of the detection modules comprises:
a comparator coupled to the calculator, for comparing the reference value with a threshold value;
an indication signal generator coupled to the comparator, for generating a primitive indication signal according to a comparison result generated by the comparator; and
a delay-matching unit coupled to the indication signal generator and the logic unit, for delaying the primitive indication signal to generate an indication signal.

10. The impulse noise remover of claim 9, wherein the indication signal generator generates the primitive indication signal to indicate an amount of invalid samples in the input signal if the comparison result indicates that the reference value exceeds the threshold value.

11. The impulse noise remover of claim 7, wherein the calculator calculates an absolute sum of signals included in the signal subset to be the reference value.

12. A method for removing impulse noise from an input signal to generate an output signal, the method comprising:
delaying the input signal to generate a plurality of delayed signals, the input signal and the delayed signals constituting a reference signal set;
generating a plurality of indication signals according to a plurality of threshold values and a plurality of signal subsets of the reference signal set;
generating a control signal according to the indication signals; and
selectively outputting a padding value or one of the delayed signals as the output signal according to the control signal.

13. The method of claim 12, wherein the signal subsets utilized in the step for generating the indication signals are different from each other.

14. The method of claim 12, wherein the threshold values utilized in the step for generating the indication signals are different from each other.

15. The method of claim 12, wherein the step for generating the indication signals comprises:
calculating a plurality of reference values according to the signal subsets;
comparing each of the reference values with one of the threshold values;
generating a plurality of primitive indication signals according to the results of the comparison step; and
delaying the primitive indication signals to generate the indication signals.

16. The method of claim 15, wherein each of the reference values is an absolute sum of signals included in one of the signal subsets.

17. The method of claim 15, wherein the step for generating the primitive indication signals comprises:
if one of the reference values exceeds one corresponding threshold value of the threshold values, generating one of the primitive indication signals to indicate an amount of invalid samples in the input signal.

18. A method for removing impulse noise from an input signal to generate an output signal, the method comprising:
delaying the input signal to generate a plurality of delayed signals, the input signal and the delayed signals constituting a reference signal set;
calculating a reference value according to a signal subset of the reference signal set;
generating a plurality of indication signals according to the reference value and a plurality of threshold values;
generating a control signal according to the indication signals; and
selectively outputting a padding value or one of the delayed signals as the output signal according to the control signal.

19. The method of claim 18, wherein the threshold values utilized in the step for generating the indication signals are different from each other.

20. The method of claim 18, wherein the step for generating the indication signals comprises:
comparing the reference value with each of the threshold values;
generating a plurality of primitive indication signals according to the results of the comparison step; and
delaying the primitive indication signals to generate the indication signals.

21. The method of claim 20, wherein the step for generating the primitive indication signals comprises:
if the reference value exceeds one of the threshold values, generating one of the primitive indication signals to indicate an amount of invalid samples in the input signal.

22. The method of claim 18, wherein the reference value is an absolute sum of signals included in the signal subset.
